(19) United States
(12) Patent Application Publication
(10) Pub. No.: US 2008/0277754 A1
(43) Pub. Date: Nov. 13, 2008

(54) IMAGE SENSOR AND FABRICATION METHOD THEREOF

(76) Inventor: Michael-Y Liu, Chiayi City (TW)

Correspondence Address: NORTH AMERICA INTELLECTUAL PROPERTY CORPORATION, P.O. BOX 506, MERRIFIELD, VA, 22116, US

(21) Appl. No.: 11/745,468

(22) Filed: May 8, 2007

(51) Int. Cl. H01L 31/0352; H01L 31/18

(52) U.S. Cl. 257/443; 438/73; 257/E31.032

(57) ABSTRACT

A method of fabricating an image sensor contains providing a semiconductor substrate with a plurality of pixels defined thereon, forming pixel electrodes on the pixels, and forming a barrier device filled between adjacent pixel electrodes, wherein the barrier device contains a high-k material. Then, a photoconductive layer and a transparent conductive layer are successively formed on the high-k material layer and the pixel electrodes.

### BACKGROUND OF THE INVENTION

1. Field of the Invention

The present invention relates to an image sensor, and more particularly, to an image sensor having a barrier device disposed between pixel electrodes.

2. Description of the Prior Art

Since related techniques have been highly developed in recent years, many kinds of image sensors have been widely applied to digital electronic products, such as scanners or digital cameras. The familiar image sensor with complementary metal oxide semiconductor (CMOS) or charge coupled device (CCD) is a silicon semiconductor device, designed to capture photons and convert them into electrons. Electrons, once converted, are then transferred and converted again to voltage which can be measured and turned into digital data.

The photoconductor-on-active-pixel (POAP) image sensor has been studied to pursue advantages over the conventional CCD or CMOS image sensor. The POAP image sensor has a hydrogenated amorphous silicon (α-Si:H) based structure stacking on CCD or CMOS elements. The high fill factor brought by its stacking structure will provide the full of pixel area to be available for photo sensing, thereby achieving the high quantum efficiency in conjunction with the direct energy transition of α-Si:H material. However, POAP image sensor still has cross-talk, image lag, and dark leakage signal problems in the past study. In particular, the problem of carrier cross-talk across adjacent pixels causes the serious resolution and uniformity degradation at the photo-response, and brings the color cross-talk over the pixels resulted in the poor color fidelity.

Please refer to FIGS. 1-2. FIG. 1 is a sectional view of a POAP image sensor 10 according to the prior art, and FIG. 2 is a potential simulation diagram of the adjacent pixel electrodes shown in FIG. 1. The prior-art image sensor 10 has a plurality of pixels 14a, 14b and a dielectric layer 16 positioned on a substrate 12, a plurality of pixel circuits (not shown) positioned in the pixels 14a, 14b, a plurality of pixel electrodes 18a, 18b positioned on the pixel circuits and the dielectric layer 16, a photo-conductive layer 20 positioned above the pixel electrodes 18a, 18b, and a transparent conductive layer 28 positioned on the photo-conductive layer 20. The photo-conductive layer 20 includes an n-type layer (n-layer) 22, an intrinsic layer (i-layer) 24, and a p-type layer (p-layer) 26 from bottom to top, forming a p-i-n stacked structure for accepting incident light and converging light into corresponding charges according to the light intension.

However, the different pixel electrodes 18a, 18b of the prior-art image sensor 10 may have various voltages under illumination, resulted in an electric filed with potential difference between the adjacent pixels 14a, 14b. For example, if the pixel electrode 18b has a high potential V_{H}, and the pixel electrode 18a has a low potential V_{L} under illumination, as the transparent conductive layer 28 is grounded, leakage current will occur between the adjacent pixels 14a, 14b, flowing from the pixel electrode 18b with the high potential V_{H} to the nearby pixel electrode 18a with the low potential V_{L}, as shown in FIG. 2. There, the cross-talk problem occurs and influence the accuracy of sensing images, resulted in poor sensing fidelity.

As a result, to improve the structure of the POAP image sensor for avoiding cross-talk problems between adjacent pixels to provide a good image-sensing performance is still an important issue for the manufacturers.

### SUMMARY OF THE INVENTION

It is a primary objective of the claimed invention to provide an image sensor with a barrier device and a fabrication method thereof for solving the above-mentioned cross-talk problem of the conventional image sensors.

According to the claimed invention, the method of fabricating an image sensor comprises providing a substrate with a plurality of pixels defined thereon, forming a plurality of pixel electrodes in the pixels on the substrate, forming a barrier device with a high-k (high dielectric constant) material filled between adjacent pixel electrodes, and successively forming a photo-conductive layer and a transparent conductive layer on the barrier device and the pixel electrodes.

According to the claimed invention, a structure of an image sensor is further provided. The image sensor comprises a semiconductor substrate, a plurality of pixels defined on the semiconductor substrate, a photo-conductive layer and a transparent conductive layer disposed on the pixel electrodes in each pixel in order, and a barrier device disposed between any two adjacent pixel electrodes. The barrier device comprises a high-k material.

It is an advantage that the barrier device with the high-k material is disposed between any adjacent pixel electrodes of the image sensor so that a high barrier occurs between the adjacent pixel electrodes so as to prevent currents pass toward a pixel electrode or the transparent conductive layer from an adjacent pixel electrode. As a result, the cross-talk problem can be avoided, and the fidelity of performance of the image sensor is improved.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a sectional schematic diagram of a POAP image sensor according to the prior art.

FIG. 2 is a potential simulation diagram of the pixel electrodes shown in FIG. 1.

FIG. 3 to FIG. 8A are schematic diagrams of the fabrication method of an image sensor according to the present invention.

FIG. 8B is a sectional schematic diagram of an image sensor according to another embodiment of the present invention.

FIG. 9 is a potential diagram of the prior-art image sensor and the present invention image sensor.

FIG. 10 is a potential simulation diagram of two adjacent pixels of the present invention image sensor.

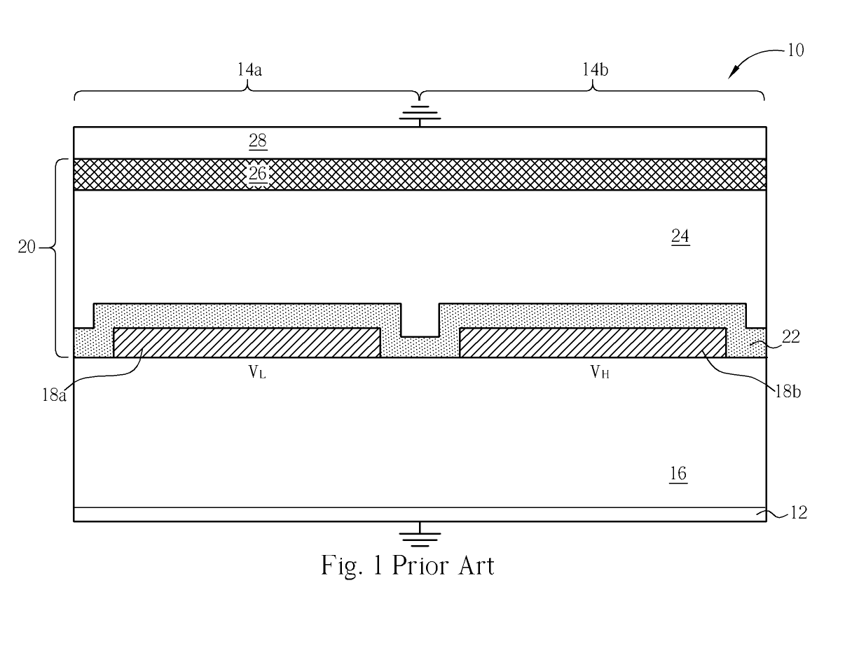

### DETAILED DESCRIPTION

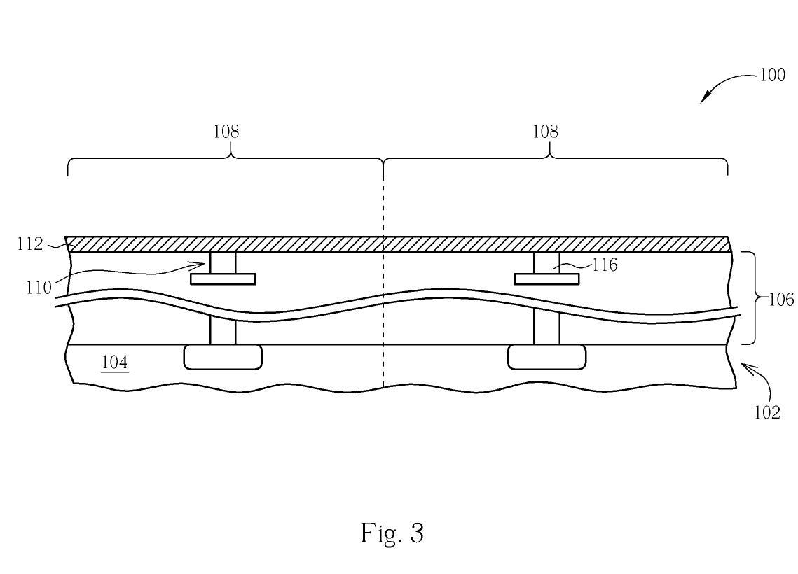

Please refer to FIGS. 3-8A. FIG. 3 to FIG. 8A are schematic diagrams of the fabrication method of an image sensor 100 according to the present invention. First, as shown in FIG. 3, a semiconductor chip 102 is provided, which comprises a semiconductor substrate 104, such as a silicon substrate. The semiconductor substrate 104 comprises a plurality of pixels 108 defined thereon, forming a pixel matrix. Then, pluralities of electric elements are formed on the semiconductor substrate 104 to form the pixel circuits 110 in the dielectric layer 106. A conductive layer 112 is formed on the dielectric layer 106, above the pixel circuits 110, wherein the conductive layer 112 may comprise metal materials, such as titanium nitride (TiN).

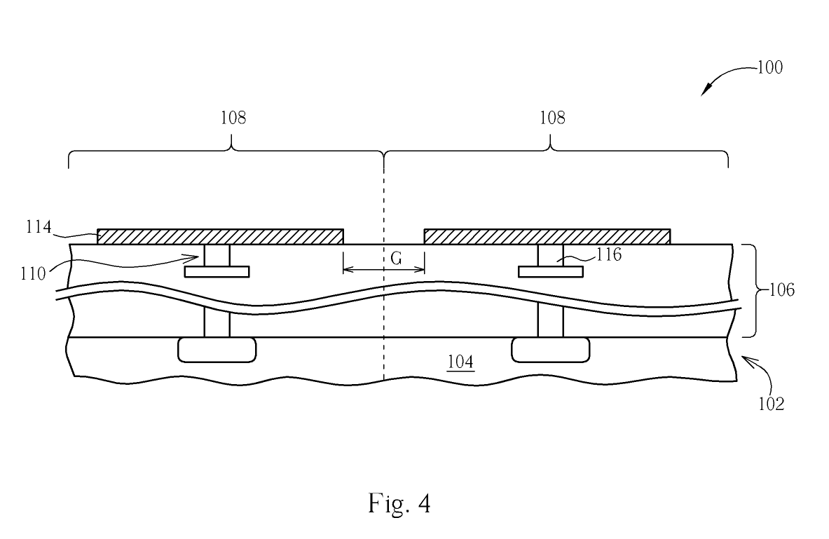

Referring to FIG. 4, then, a photolithography-etching-process (PEP) is performed as the following description. A photoresist layer (not shown) is formed on the surface of the semiconductor substrate 104, a photomask with a pixel electrode pattern is used to define a pixel electrode pattern on the photoresist layer, an etching process is carried out to remove portions of the conductive layer 112, and the photoresist layer is removed. Accordingly, the residual conductive layer 112 forms pixel electrodes 114 in each pixel 108, which are electrically connected to the corresponding pixel circuits 110 through the contact holes 116. In addition, an electrode gap G is formed between adjacent pixel electrodes 114.

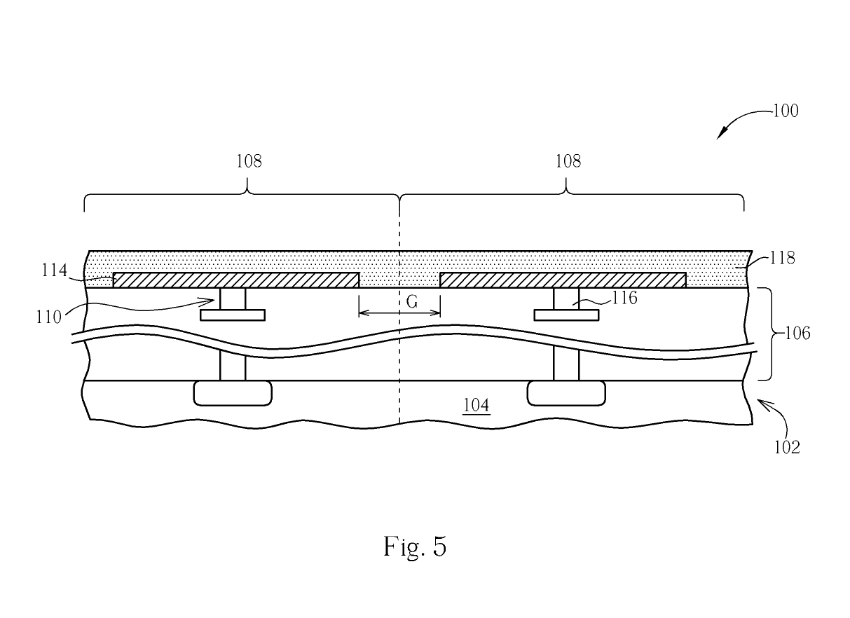

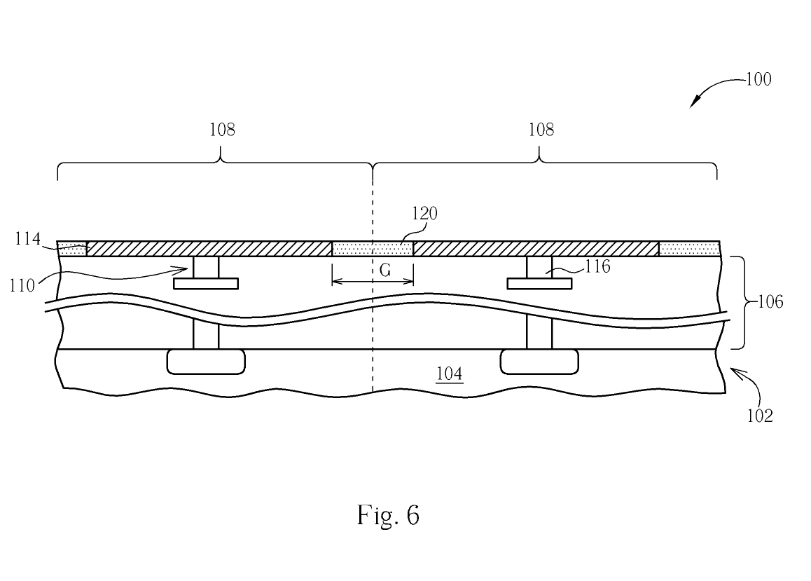

Thereafter, a barrier device 120 is formed between adjacent pixel electrodes 114. The formation method of the barrier device 120 is illustrated in FIGS. 5-6. First, as shown in FIG. 5, a high-k material layer 118 is formed on the semiconductor substrate 104 to cover the dielectric layer 106 and the pixel electrodes 114, while portions of the high-k material layer 118 are also filled into the electrode gap G of the adjacent pixel electrodes 114. The high-k material layer 118 may be formed by a chemical vapor deposition (CVD) process or a physical vapor deposition (PVD) process. The dielectric constant of the high-k material layer 118 may be approximate about 25 to 30, and may comprise tantalum pentoxide (Ta₂O₅) material. Then, referring to FIG. 6, a chemical mechanical polishing (CMP) process or an etching back process is performed to remove a portion of the high-k material layer 118 positioned above the surfaces of pixel electrodes 114 so that the thickness of the high-k material layer 118 is approximately the same as the thickness of the pixel electrodes 114, which means the top surfaces of the pixel electrodes 114 and the residual high-k material layer 118 are at a same plane. The residual high-k material layer 118 is considered as a barrier device 120 disposed between adjacent pixel electrodes 114. Since the barrier device 120 is formed with the high-k material layer 118 that fills the electrode gap G, the bottom surface of the barrier device 120 and the bottom surfaces of the pixel electrodes 114 are approximate at the same plane, which is the top surface of the dielectric layer 106.

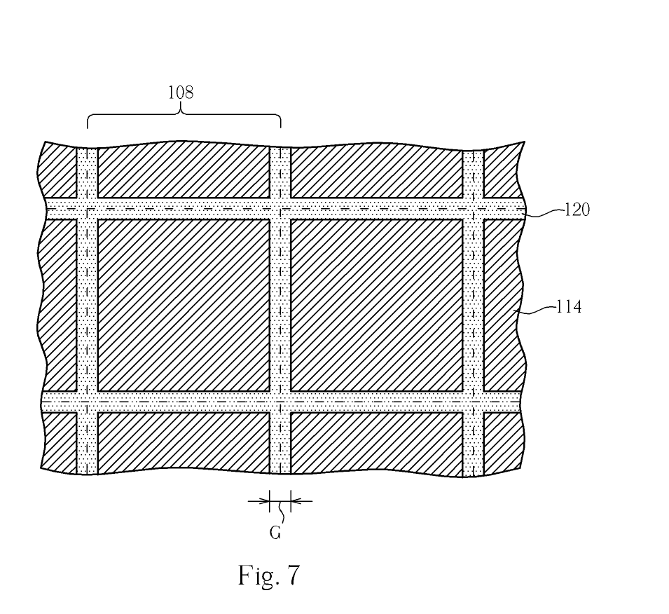

Please refer to FIG. 7, wherein FIG. 7 is a top-view of the pixel electrodes 114 and the barrier device 120 shown in FIG. 6. The pixels 108 are defined on the semiconductor substrate 104 and arrange as a pixel matrix. Each pixel 108 contains a pixel electrode 114, and the barrier device 120 is formed between adjacent pixel electrodes 114, as a mesh around each of the pixel electrodes 114.

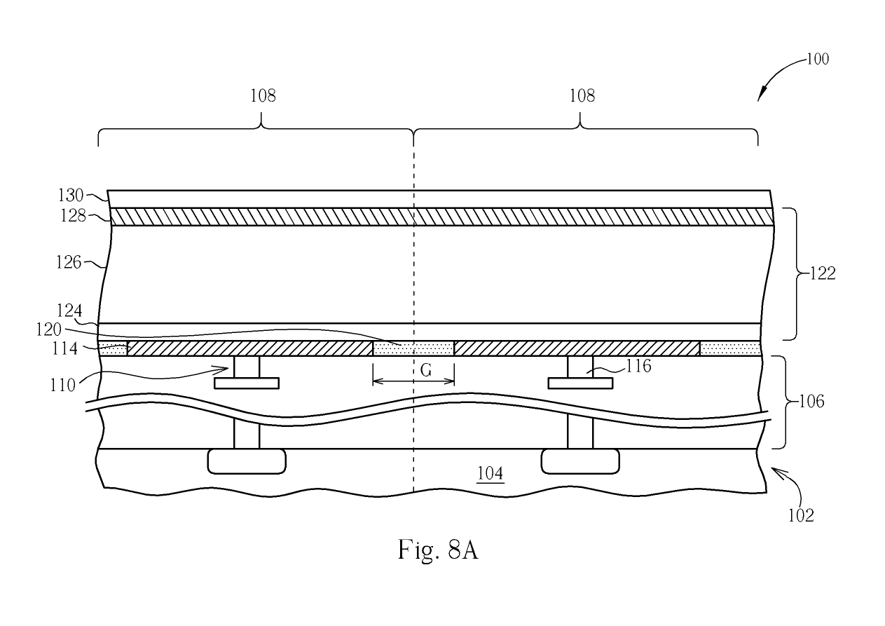

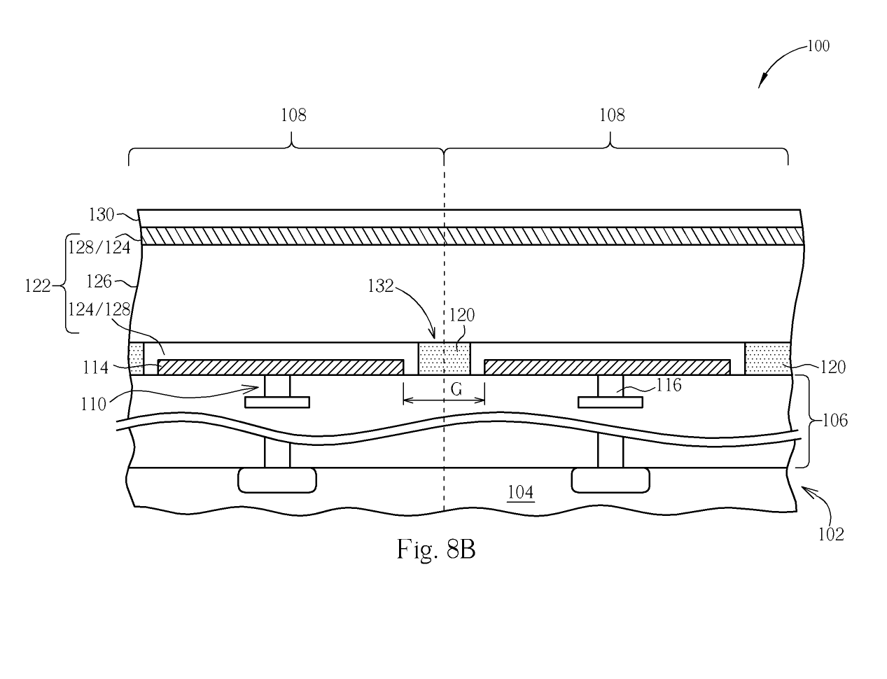

Referring to FIG. 8A, then, a photo-conductive layer 122 and a transparent conductive layer 130 are successively formed on the surface of the semiconductor substrate 104. The photo-conductive layer 122 comprises an n-layer 124, an i-layer 126, and a p-layer 128 from bottom to top. The n-layer 124 and the p-layer 128 may comprise hydrogenated amorphous silicon carbide (α-SiC:H) with n-type dopants and p-type dopants respectively, while the i-layer 126 may comprise hydrogenated amorphous silicon (α-Si:H). As shown in FIG. 8A, the n-layer 124 formed above the pixel electrodes 114 directly contacts the barrier device 120 and the pixel electrodes 114, and is a continuous layer covering the pixel electrodes 114 and the barrier device 120. However, in other embodiments, the photo-conductive layer 122 may comprise a p-layer, an i-layer, and an n-layer from bottom to top. In addition, the transparent conductive layer 130 may comprise indium tin oxide (ITO). After the photo-conductive layer 122 and the transparent conductive layer 130 are fabricated, the formation of the POAP image sensor 100 of the present invention is completed.

In other embodiments of the present invention, the n-layer 124/p-layer 128 of the photo-conductive layer 122 may be formed on the pixel electrodes 114 before forming the barrier device 120. Then, a dry etching process is performed to remove portions of the n-layer 124/p-layer 128 for forming a plurality of recess 132 positioned between adjacent pixel electrodes 114. Before the dry etching process, a photoresist layer with a pattern similar to bout a little wider than the pattern of the pixel electrodes 114 may be formed on the n-layer 124/p-layer 128 and used as an etching mask. Then, high-k materials are filled into the recess 132 to form the barrier device 120. Therefore, the n-layer 124/p-layer 128 is a discontinuous layer covering the pixel electrodes 114 and is separated by the barrier device 120. The top surface of the barrier device 120 and the top surface of the n-layer 124/p-layer 128 are approximately at the same plane. The formation processes of the barrier device 120 may comprise performing a CVD or PVD process to form a high-k material layer (not shown) on the semiconductor substrate 104, covering the n-layer 124/p-layer 128 and filling the recess 132, and carrying out a CMP process or an etching back process to remove portions of the high-k material layer higher than the surface of the n-layer 124/p-layer 128. Then, the i-layer 126, the p-layer 128/n-layer 124, and the transparent conductive layer 130 are successively formed on the semiconductor substrate 104 to complete the fabrication of the POAP image sensor 100 shown in FIG. 8B.

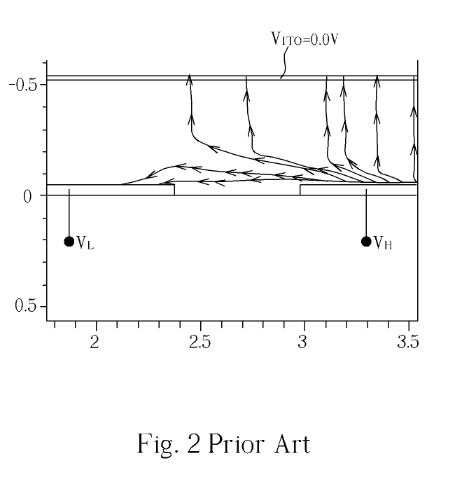

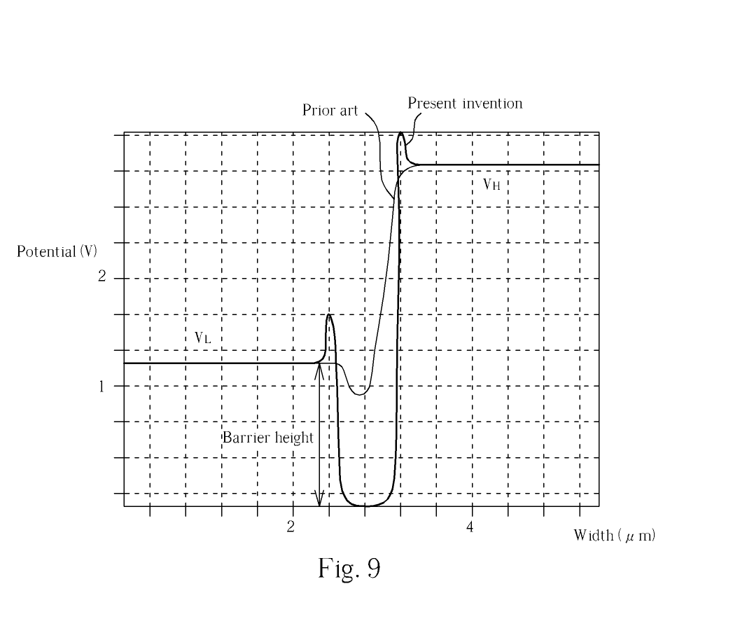

Please refer to FIG. 9. FIG. 9 is a potential diagram of the prior-art image sensor 10 and the image sensor 100 of the present invention. When the two adjacent pixel electrodes have a low potential V_{L} and a high potential V_{H} respectively, there is no potential barrier height or only a few potential barrier height in the electrode gap between the two pixel electrodes 18a, 18b of the prior-art image sensor 10. Therefore, the electrons generated in the i-layer 24 easily flow from the left pixel electrode 18a with the low potential V_{L} to the right pixel electrode 18b with the high potential V_{H}, occurring cross-talk problems (as shown in FIG. 2). In contrary, although the two adjacent pixel electrodes 114 of the present invention image sensor 100 have a high potential V_{H} and a low potential V_{L} respectively, there is a big barrier height generated in the electrode gap G of the pixel electrodes 114 that avoids the cross-talk problem, as shown in FIG. 9.

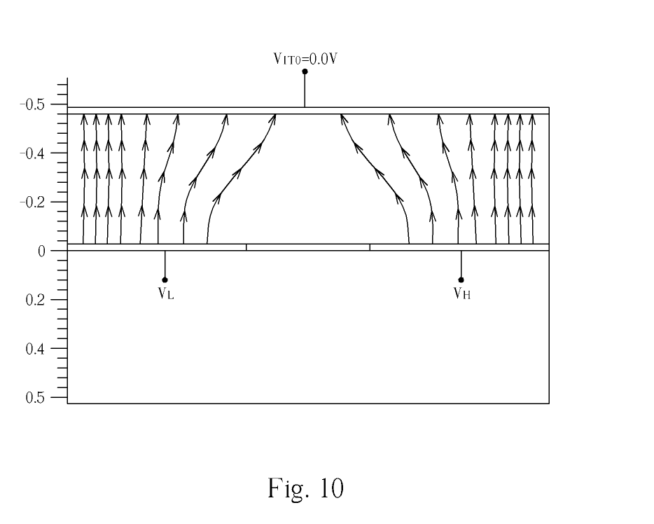

Referring to FIG. 10, which is a potential simulation diagram of two adjacent pixels 108 of the present invention image sensor 100. The two pixel electrodes 114 have a high potential V_{H} and a low potential V_{L} respectively, but currents do not flow from the right pixel electrode 114 with the high potential V_{H} to the left pixel electrode 114 with the low potential V_{L} because the barrier device 120 provides a high barrier height in the electrode gap G between the adjacent pixel electrodes 114. Therefore, carrier cross-talk will not occur to influence the color fidelity of sensed images of the image sensor 100.

In contrast to the prior art, a barrier device is disposed between adjacent pixels or adjacent pixel electrodes of the image sensor of the present invention such that a high barrier height occurs at the electrode gap. Accordingly, the cross-talk problem is avoided to improve the performance of the image sensor. In addition, since the barrier device of the present invention is composed of high-k material, it can barricade the electric field arrangement between adjacent pixels so that the cross-talk problem, resulting from the leakage currents between pixel electrodes, can be avoided. Accordingly, the structure of the present invention image sensor without the cross-problem problem can be fabricated with simple processes and low cost to effectively increase the performance.

Those skilled in the art will readily observe that numerous modifications and alterations of the device and method may be made while retaining the teachings of the invention.

What is claimed is:

1. A method of fabricating an image sensor, comprising:
providing a semiconductor substrate with a plurality of pixels defined thereon;
forming a plurality of pixel electrodes on the semiconductor substrate in the pixels;
forming a barrier device filled between any two of the adjacent pixel electrodes, the barrier device comprising a high-k (high dielectric constant) material; and
successively forming a photo-conductive layer and a transparent conductive layer on the barrier device and the pixel electrodes.

2. The method of claim 1, wherein a formation method of the barrier device comprises:
forming a high-k material layer on the semiconductor substrate to cover the pixel electrodes; and
removing portions of the high-k material layer positioned above surfaces of the pixel electrodes.

3. The method of claim 2, wherein the step of formation the high-k material layer comprises performing a physical vapor deposition (PVD) process or a chemical vapor deposition (CVD) process.

4. The method of claim 2, wherein the step of removing portions of the high-k material layer comprises a chemical mechanical polishing process (CMP) or an etching back process.

5. The method of claim 1, wherein a thickness of the barrier device is approximately the same as the thickness of the pixel electrodes.

6. The method of claim 1, wherein a dielectric constant of the high-k material is between about 25 to 30.

7. The method of claim 1, wherein the high-k material comprises tantalum pentoxide (Ta₂O₅).

8. The method of claim 1, wherein the photo-conductive layer comprises an n-type layer (n-layer), an intrinsic layer (i-layer), and a p-type layer (p-layer) which are stacked in order.

9. The method of claim 1, wherein the barrier device is as a mesh around each of the pixel electrodes.

10. An image sensor comprising:
a semiconductor substrate;
a plurality of pixels defined on the semiconductor substrate, each of the pixels comprising a pixel electrode;
a photo-conductive layer and a transparent conductive layer disposed on the pixel electrodes in order; and
a barrier device disposed between any two of the adjacent pixel electrodes, the barrier device comprising a high-k material.

11. The image sensor of claim 10, wherein a dielectric constant of the high-k material is between about 25 to 30.

12. The image sensor of claim 10, wherein the high-k material comprises Ta₂O₅.

13. The image sensor of claim 10, wherein the barrier device is as a mesh round each of the pixel electrodes.

14. The image sensor of claim 10, wherein a bottom surface of the barrier device and bottom surfaces of the pixel electrodes are approximately at a same plane.

15. The image sensor of claim 10, wherein the photo-conductive layer comprises a first conductive type doped layer, an intrinsic layer, and a second conductive type doped layer which are stacked in order.

16. The image sensor of claim 15, wherein the first conductive type doped layer and the second conductive type doped layer comprise hydrogenated amorphous silicon carbide (α-SiC:H) materials.

17. The image sensor of claim 15, wherein the intrinsic layer comprises a hydrogenated amorphous silicon (α-Si:H) material.

18. The image sensor of claim 15, wherein the first conductive type doped layer is a continuous layer covering the pixel electrodes and the barrier device.

19. The image sensor of claim 15, wherein the first conductive type doped layer is a discontinuous layer covering the pixel electrodes and is separated by the barrier device.

20. A method of fabricating an image sensor, comprising:
providing a semiconductor substrate with a plurality of pixels defined thereon;
forming a plurality of pixel electrodes in the pixels on the semiconductor substrate;
forming a first conductive type doped layer on the semiconductor substrate, covering the pixel electrodes;
removing a portion of the first conductive type doped layer to form a recess between any two of the adjacent pixel electrodes;
forming a barrier device filling in the recess, the barrier device comprising a high-k material; and
successively forming an intrinsic layer, a second conductive type doped layer, and a transparent conductive layer on the semiconductor substrate.

21. The image sensor of claim 20, wherein the first conductive type doped layer comprises an n-type layer, and the second conductive type doped layer comprises a p-type layer.

22. The image sensor of claim 20, wherein the first conductive type doped layer comprises a p-type layer, and the second conductive type doped layer comprises an n-type layer.

23. The image sensor of claim 20, wherein a formation method of the barrier device comprises:
forming a high-k material layer on the semiconductor substrate; and
removing portions of the high-k material layer positioned above a surface of the first conductive type doped layer.

24. The image sensor of claim 23, wherein the step of forming the high-k material layer comprises a PVD or a CVD process.

25. The image sensor of claim 23, wherein the step of removing portions of the high-k material layer comprises a CMP process or an etching back process.

26. The image sensor of claim 20, wherein a top surface of the barrier device and a top surface of the first conductive type doped layer are approximately at a same plane.

27. The image sensor of claim 20, wherein a dielectric constant of the high-k material is about 25 to 30.

28. The image sensor of claim 20, wherein the high-k material comprises Ta₂O₅.

29. The image sensor of claim 20, wherein the first conductive type doped layer, the intrinsic layer, and the second conductive type doped layer forms a photo-conductive layer.

30. The image sensor of claim 20, wherein the barrier device is as a mesh around each of the pixel electrodes.
